(19) United States
(12) Patent Application Publication
(10) Pub. No.: US 2023/0094955 A1
(43) Pub. Date: Mar. 30, 2023

(54) Partial Fourier Method with Neural Networks

(71) Applicant: Siemens Healthcare GmbH, Erlangen (DE)

(72) Inventor: Mario Zeller, Erlangen (DE)

(73) Assignee: Siemens Healthcare GmbH, Erlangen (DE)

(21) Appl. No.: 17/955,735

(22) Filed: Sep. 29, 2022

(30) Foreign Application Priority Data
Sep. 29, 2021 (EP) 21199876.0

(51) Int. Cl. G06N 3/08; G06F 17/14

(52) U.S. Cl. CPC G06N 3/08; G06F 17/14

(57) ABSTRACT

An inventive computer-implemented method for creating correction data, which corrects measurement data missing in a measurement dataset recorded using a partial Fourier technique (PF technique), i.e. measurement data which was not recorded even though this is required in accordance with Nyquist for a complete measurement dataset, may include: receiving input data created on the basis of measurement data in the measurement dataset, applying at least one trained correction function to the input data to determine output data, and providing the output data. The output data may include correction information that corrects measurement data missing in the measurement dataset.

### CROSS REFERENCE TO RELATED APPLICATIONS

This patent application claims priority to European Patent Application No. 21199876.0, filed Sep. 29, 2021, which is incorporated herein by reference in its entirety.

### BACKGROUND

### Field

The disclosure relates to a partial Fourier method with neural networks.

### Related Art

The magnetic resonance technique (the abbreviation MR stands for magnetic resonance below) is a known technique with which images of the interior of an object under examination can be generated. In simplified terms, the object under examination is for this purpose positioned in a magnetic resonance device in a comparatively strong static, homogeneous constant magnetic field, also called a B₀ field, with field strengths of 0.2 tesla to 7 tesla and more, so that its nuclear spins are oriented along the constant magnetic field. To trigger nuclear spin resonances that can be measured as signals, radiofrequency excitation pulses (RF pulses) are irradiated into the object under examination, the triggered nuclear spin resonances are measured as what is known as k space data and on the basis thereof MR images are constructed or spectroscopy data is determined. For position encoding of the measurement data, rapidly switched magnetic gradient fields, called gradients for short, are superimposed on the constant magnetic field. A diagram used, which describes a sequence over time of RF pulses to be irradiated and gradients to be switched, is referred to as a pulse sequence (diagram), or else as a sequence for short. The plotted measurement data is digitized and stored as complex numerical values in a k space matrix. An associated MR image can be reconstructed from the k space matrix populated with values, e.g. by means of a multidimensional Fourier transform.

In order to improve the signal-to-noise ratio or reduce the sensitivity of movement and/or flow of the measurement in MR measurements, it is already common in many recordings to record measurement data multiple times, in order to be able to undertake averaging of the measurement data or e.g. of the reconstructed image data.
In addition, in many examinations it is however also necessary to carry out multiple, i.e. a whole series of magnetic resonance recordings of the object under examination, wherein a particular measurement parameter is varied. On the basis of the measurements the effect of this measurement parameter on the object under examination is observed, in order then subsequently to draw diagnostic conclusions therefrom. A series should in this case be understood to mean at least two, but generally more than two, recordings of measurement datasets. A measurement parameter is in this case expediently varied such that the contrast of a particular type of material excited during the measurements, for example of a tissue type of the object under examination or of a chemical substance that is significant for most or particular tissue types, such as e.g. water, is influenced as strongly as possible by the variation of the measurement parameter. This ensures that the effect of the measurement parameter on the object under examination is particularly clearly visible.
A typical example of series of magnetic resonance recordings subject to the variation of a measurement parameter strongly influencing the contrast are so-called “diffusion weighting imaging” (DWI) methods. Diffusion is understood as the Brownian motion of molecules in a medium. In diffusion imaging, multiple images with different diffusion directions and weightings are generally recorded and are combined with one another. The strength of the diffusion weighting is usually defined by what is known as the “b value”. The diffusion images with different diffusion directions and weightings or the images combined therefrom can then be used for diagnostic purposes. Thus, by suitable combinations of the recorded diffusion-weighted images it is possible to generate parameter maps with particular diagnostic validity, for example maps showing the “Apparent Diffusion Coefficient (ADC)” or the “Fractional Anisotropy (FA)”.

In diffusion-weighted imaging additional gradients that reflect a respective diffusion direction and a respective diffusion weighting are inserted into a pulse sequence, in order to make the diffusion properties of the tissue visible or to measure them. These gradients mean that tissue with a rapid diffusion (e.g. cerebral spinal fluid (CSF)) is subject to a stronger signal loss than tissue with a slow diffusion (e.g. the gray matter in the brain). The resulting diffusion contrast is becoming increasingly clinically meaningful and applications now extend far beyond the traditional early identification of ischemic stroke.

Diffusion imaging is frequently based on echo planar imaging (EPI) because of the short acquisition time of the EPI sequence per image and its robustness with respect to movement.

MR images recorded using EPI methods can have local geometric distortions that are caused for example by inhomogeneities in the constant magnetic field. The inhomogeneities can be brought about by susceptibility discontinuities at tissue interfaces, e.g. in the case of transitions from air to tissue of the object under examination, for example in the case of human or animal patients as an object under examination transitions from bone to softer tissue, and result in local phase accumulations via the readout echo train of the EPI measurement. To minimize the strength of the geometric distortions an attempt can be made to minimize the phase accumulation. To this end the echo train can for example be kept as short as possible, although this restricts the spatial resolution, or parallel imaging techniques can be employed. Further effects, such as (pulsing) movements in the target area of the object under examination, from which measurement data is recorded, can result in (further) phase errors.

It is further possible to record the k space in segments, i.e. to perform the recording of measurement data on a segmented basis. In principle the segmentation of the k space can take place in the phase encoding direction and/or in the readout direction.

The RESOLVE sequence first described in the article by Porter and Heidemann “High Resolution Diffusion-Weighted Imaging Using Readout-Segmented Echo-Planar Imaging, Parallel Imaging and a Two-Dimensional Navigator-Based Reacquisition”, MRM 62, 2009, p. 468-475, is a variant of an EPI-type sequence, in which a segmentation takes place in the readout direction instead of in the phase encoding direction. A RESOLVE sequence can be combined with diffusion preparation and/or with navigator measurements.

In general terms, in the case of a RESOLVE sequence after diffusion preparation by a prephasing gradient the segment of the k space that is to be filled with measurement data in the subsequent readout phase can be established. In the readout phase a train of echo signals is captured as measurement data for the established segment by means of a sinusoidal readout gradient. By means of a further gradient that has an opposing polarity to that of the prephasing gradient and can be switched following the readout phase, it is possible to return to the k space center again in the readout direction, before a further refocusing pulse can be irradiated that results in the formation of further echo signals that are captured as navigator data of the k space center by means of a navigator readout gradient. The navigator data thus captured for each segment can be used to correct possible phase changes between the capture of the measurement data in the individual segments, as is described in greater detail in the aforementioned article by Porter and Heidemann.

To reduce the duration of a recording of a complete measurement dataset in accordance with Nyquist, it is possible under particular circumstances for particular measurement data in the complete set not to be recorded, but to be added later. Less time is required to record an incomplete measurement dataset than to record a complete measurement dataset. A method such as this is for example a partial Fourier (PF) technique. In PF techniques it is normally not the whole k space that is sampled, in other words recorded or measured, but, in a k space direction (PF direction), only a part of the k space specified by a PF factor and further determined by symmetry considerations of the k space. The symmetry of the k space is used in PF techniques to supplement or fill up the unmeasured part of the k space using various reconstruction methods. In a method referred to as “zero-filling”, unrecorded areas of the k space are filled with zeroes or zero values. This is a very simple method that requires little computing power, but it does not always deliver satisfactory results.

An alternative method of supplementing unrecorded measurement data in PF methods uses what is known as a POCS algorithm (Projection Onto Convex Sets), which estimates missing, in other words unmeasured, parts of the k space of a measurement dataset in an iterative process, thereby ensuring data consistency with the actually measured parts of the k space of the measurement dataset, in other words actually measured k space values. To this end reference can for example be made to the publication “Implementation and Assessment of Diffusion-Weighted Partial Fourier Readout-Segmented Echo-Planar Imaging” by Robert Frost et. al. in Magnetic Resonance in Medicine 68:441-451 (2012). This methodology can result in improved sharpness or spatial resolution but cannot always be reliably used, for example depending on particular phase variations in the underlying measurement dataset.

Especially in segmented recording techniques, such as in particular the aforementioned RESOLVE technique which is prone to phase changes, phase inconsistencies contained in the measurement datasets between the individual segments in conjunction with PF techniques can result in artifacts, in particular what are known as ringing artifacts and/or grid-type mesh artifacts, in particular in the case of higher PF factors. As a result, an increase in speed of the measurement data recording that can be achieved using a PF technique is often limited.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a flowchart of a method according to an exemplary embodiment of the present disclosure.

FIG. 2 shows schematically represented examples of measurement data in a measurement dataset recorded in the k space using a PF technique, according to an exemplary embodiment of the present disclosure.

FIG. 3 shows a structure of a trained correction function according to an exemplary embodiment of the present disclosure.

FIG. 4 shows an assignment device according to an exemplary embodiment of the present disclosure.

FIG. 5 shows a magnetic resonance system according to an exemplary embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to prevent artifacts in conjunction with PF methods, thereby permitting larger PF factors in order to be able to further reduce the time needed to record the measurement data. To this end, it should in particular be made possible to be able to correct the absence of measurement data in a measurement dataset recorded using a PF technique, as if, for a measurement dataset recorded using a PF technique, measurement data had not been recorded reduced by a PF factor in the PF direction, but had all been recorded, as if the measurement dataset had been sampled completely in the PF direction in accordance with Nyquist.

The object is achieved by the aspects of the disclosure, including by a method for creating correction data, a method for preventing artifacts in image data reconstructed from a measurement dataset recorded using a PF technique, a correction processor, a magnetic resonance system, a computer program product, and an electronically readable data storage medium.

An inventive computer-implemented method for creating correction data, which corrects measurement data missing in a measurement dataset recorded using a partial Fourier technique (PF technique), i.e. measurement data which was not recorded even though this is required in accordance with Nyquist for a complete measurement dataset, may include:
receipt of input data created on the basis of measurement data in the measurement dataset,
application of at least one trained correction function to the input data, wherein output data comprising correction information that corrects measurement data missing in the measurement dataset is determined,
provision of the output data.

The inventive correction method thus permits effects caused in a loaded measurement dataset by measurement data that is missing because a PF technique has been used to be corrected by the provision of output data that comprises correction information. The correction information can in this case be configured in various ways, depending on the type of output data, but in each case, it brings about a correction of the missing measurement data, so that by means of the output data the missing measurement data can be directly or indirectly replaced, as if it had been recorded. In particular, artifacts in image data caused by measurement data not being recorded because a PF technique was used and that therefore is missing, can be prevented in this way, with an achievable image sharpness simultaneously being increased.

In accordance with the disclosure it is consequently proposed to employ artificial intelligence, in particular one or more neural networks, to achieve a fast and reliable correction of missing measurement data in measurement datasets recorded using a PF technique. In this way an automated correction of information not recorded by the PF technique is consequently also possible with higher PF factors, as a result of which the time needed to record the measurement data can be reduced, without any diminution in an image quality of image data reconstructed on the basis of the recorded measurement data, and in fact the image quality may even be improved.

In general, a trained function, thus consequently also the trained correction function, maps cognitive functions that humans associate with other human brains. Thanks to training based on training data (machine learning) the trained function is able to adapt itself to new circumstances and to detect and extrapolate patterns.

Generally speaking, parameters of a trained function can be adapted by training. In particular, supervised learning, semi-supervised learning, non-supervised learning, reinforcement learning and/or active learning can be used. In addition, representation learning (also known as “feature learning”) can be employed. The parameters of the trained function can in particular be adapted iteratively by multiple training steps.

A trained function can for example comprise a neural network, a support vector machine (SVM), a decision tree and/or a Bayes network and/or the trained function can be based on k means clustering, Q learning, genetic algorithms and/or assignment rules. In particular, a neural network can be a deep neural network, a convolutional neural network (CNN), in particular a CNN consisting only of convolutional layers, or a deep CNN. In addition, the neural network can be an adversarial network, a deep adversarial network and/or a generative adversarial network (GAN).

The trained correction function can particularly advantageously comprise a convolutional neural network (CNN). The CNN can particularly advantageously be a U-shaped neural network, in particular a U-net, or an (inverse U-shaped) up-down network. Such (inverse) U-shaped networks have proven their worth in image processing, in particular in image-to-image networks. However, other network architectures can of course also be used.

In general, it can be said that CNNs, including those that can be employed as a trained correction function, have a convolutional basis for the generation of features from the input data, in particular from input data determined from measurement datasets recorded by means of magnetic resonance techniques, which in particular can comprise convolutional layers and pooling layers. The convolutional basis is then normally followed by a classifier, which may comprise one or more fully connected layers. The main aim of the classifier is the classification of the input data based on the features extracted by means of the convolutional basis. In other words, feature extraction in the convolutional basis is followed by a classification in the classifier, in order to provide the output data. For example, a U-net converts the input data via the convolutional basis for feature extraction into a vector (“down”) and back via an identical convolutional basis, again increasing the resolution, into data corresponding to the input data (“up”). As a result, the structure of the input data is preserved in the output data, as a result of which e.g. distortions in image data are prevented as input data and output data. An up-down network acts in an inverse manner to a U-net and initially increases the resolution (“up”) on a convolutional basis, in order then to carry out a feature extraction (“down”), wherein likewise the structure of the input data corresponds to the structure of the output data. Using a network preserving the structure in this way, information for subareas of the structure can be represented in the output data, e.g. in the case of image data as input data, information can be represented pixel by pixel in the corresponding output data.

In a first concrete embodiment of the present disclosure it can be provided that at least one trained correction function is used which as input data obtains an image dataset reconstructed from the recorded measurement dataset, and provides an image dataset as output data, in which the sharpness of the image is increased compared to the input data, as if the loaded measurement dataset had been fully sampled in the PF direction. The increased image sharpness thus corresponds to an image sharpness as is achieved in reconstruction of image datasets from measurement datasets fully sampled in the PF direction.

In a second concrete embodiment of the present disclosure it can be provided that at least one trained correction function is used, which as input data obtains an image dataset reconstructed from the recorded measurement dataset, and provides an image dataset as output data, which corresponds to a set of difference image data, which is a difference between an image dataset in which the image sharpness is increased compared to the input data, as if the loaded measurement dataset had been fully sampled in the PF direction, and the input data. In this way the trained correction function is trained in a focused manner to the differences between an image dataset reconstructed from the loaded measurement dataset and an image dataset with increased image sharpness as is achieved during reconstruction of image datasets from measurement datasets completely sampled in the PF direction, as a result of which image artifacts can be particularly well prevented. Furthermore, when difference data is taken into consideration it is particularly easily possible to carry out a consistency check on the output data with the input data as a plausibility check on the output data. An image dataset with increased image sharpness can then be obtained by combining the input data with the output data.

For the first and the second embodiment it can be provided that the trained correction function is trained with training input data and training output data that was obtained from measurement datasets recorded completely (in accordance with Nyquist). To generate training input data, measurement data can here again be removed in a loaded complete measurement dataset in a PF direction, before an image dataset is generated as training input data from a reduced measurement dataset obtained in this way. A generation of training input data can thus comprise loading completely sampled measurement datasets and removing measurement data, e.g. in a number of segments of the measurement dataset corresponding to a desired PF factor. Furthermore, the generation of training input data can comprise a mirroring or a complex conjugation of the k space of measurement datasets from which measurement data has already been removed or from which measurement data still has to be removed. Training output data can be generated by reconstructing an image dataset from the completely recorded measurement data, from which training input data was generated, said image dataset if necessary being processed with image data reconstructed from the generated training input data to form difference data.

In a third embodiment of the present disclosure it can be provided that at least one trained correction function is used which as input data obtains hybrid spatial data reconstructed from the recorded measurement dataset, and provides hybrid spatial data as output data, in which the image sharpness in the PF direction is increased compared to the input data, as if the loaded measurement dataset had been completely sampled in the PF direction. By using hybrid spatial data as input data and output data the trained correction function is concentrated on the direction of the spatial component, preferably the direction incompletely sampled by the PF technique. Image datasets with increased image sharpness can be reconstructed from the hybrid spatial data, e.g. by a further Fourier transform in the direction of the dimension of the hybrid spatial data still situated in the k space.

For this third embodiment it can be provided that the trained correction function is trained with training input data and training output data that was obtained from measurement datasets recorded completely (in accordance with Nyquist). To generate training input data, measurement data can here again be removed in a loaded complete measurement dataset in a PF direction, before a reduced measurement dataset obtained in this way, e.g. by a Fourier transform in the PF direction, is transposed into hybrid spatial data. A generation of training input data can here again comprise loading completely sampled measurement datasets and removing measurement data, e.g. in a number of segments of the measurement dataset corresponding to a desired PF factor. Furthermore, the generation of training input data can comprise a mirroring or a complex conjugation of the k space of measurement datasets from which measurement data has already been removed or from which measurement data still has to be removed. Training output data can be generated by creating hybrid spatial data, e.g. by an identical Fourier transform, from the completely recorded measurement data from which training input data was generated. It is also conceivable for training output data to be generated by transposing measurement data removed in the originally loaded complete measurement dataset into hybrid spatial data as training output data. By generating training output data from measurement data removed in the originally loaded complete measurement dataset, by discriminative selection of the removed measurement data used for the generation of the training output data, an increased amount of training output data can be generated.

In a fourth embodiment of the present disclosure it can be provided that at least one trained correction function is used, which obtains reconstructed image datasets or sets of hybrid spatial data or measurement data (in the k space) from different areas of a recorded measurement dataset as input data, and provides image datasets or sets of hybrid spatial data or measurement data (in the k space) from missing areas in the recorded measurement dataset or from the recorded and unrecorded measurement data in the recorded measurement dataset as output data. The loaded measurement dataset can in this case in particular already be recorded segment by segment, wherein one segment of the segment by segment recording of the measurement dataset can correspond to an area used for the generation of input data, but does not have to do so. By using areas, which can also comprise just one k space line, of the recorded measurement dataset in the generation of the input data, errors that can arise when individual areas of a recorded measurement dataset are combined can be prevented, without further (segment) fitting procedures that would otherwise have to be applied. In a variant of this embodiment the input data can directly be the measured measurement data present in the loaded measurement dataset and the output data can be the measurement data missing in the loaded measurement dataset or a measurement dataset supplemented to form a complete measurement dataset.

For this fourth embodiment it can be provided that the trained correction function is trained with training input data and training output data that was obtained from measurement datasets recorded completely (in accordance with Nyquist) segment by segment, the segments of which were correlated using a segment fitting algorithm. Further training input data and/or training output data can be generated from different fitted measurement datasets that are generated e.g. by a readjustment, in particular a manual or semi-automatic readjustment, of the results of an originally used segment fitting algorithm. Otherwise it is possible to proceed analogously to the preceding embodiments.

An expedient, general development of the disclosure can provide that the input data furthermore, i.e. additionally, comprises navigator data which is assigned to the loaded measurement dataset. As a result, information contained, e.g. in the navigator data, about a phase position during the recording of the measurement dataset, e.g. a background phase, can also be used in the trained correction function. As a result, a stabilization of the output data can be achieved, e.g. even if strong phase variations exist between individual recorded segments of the recorded measurement dataset.

Consequently, with the inventive method a PF factor with which measurement datasets are recorded can be increased compared to methods used hitherto and thus the time needed to record a measurement dataset can be reduced, wherein an image quality achieved by an inventive method of image datasets reconstructed on the basis of measurement data of a loaded measurement dataset and associated loaded output data nevertheless does not decrease, but is even increased. In this case use is made of a trained correction function, for example in a U-net architecture.

Besides the method the disclosure also relates to a correction processor for creating correction data, which corrects measurement data missing in a measurement dataset recorded using a PF technique, having
a first interface for receiving input data created on the basis of measurement data in the measurement dataset,
a correction unit for applying at least one trained correction function to the input data, wherein output data comprising correction information is determined, and
a second interface (43) for providing the output data, wherein the correction processor is configured such that it carries out a method described herein.

In other words, the correction processor, which in general comprises at least one processor and/or at least one storage means, is configured to carry out the inventive correction method. All explanations relating to the inventive method can be transferred analogously to the inventive correction processor, with which consequently likewise the aforementioned advantages can be obtained.

The correction processor can for example be implemented as part of an evaluation device. For example, the correction processor can be used as part of a controller of a magnetic resonance system, in order in particular for measurement data recorded in the postprocessing to be employed. Other embodiments are of course conceivable.

An inventive magnetic resonance system comprises a magnet unit, a gradient unit, a radiofrequency unit and a controller with a correction processor configured to carry out an inventive method.

An inventive computer program can be loaded directly into a memory of a computing device, in particular a correction processor, and has program means to carry out the steps of an inventive method, when the computer program is executed on the computing device. The computer program can be stored on an inventive electronically readable data storage medium, which consequently comprises control information stored thereon that comprises at least one inventive computer program and when the data storage medium is used in a computing device configures this so as to execute the inventive method. The data storage medium can in particular also be a non-transient data storage medium, for example a CD-ROM or a USB stick.

The advantages and explanations specified in respect of the method and/or the correction processor also apply analogously for the magnetic resonance system, the computer program product and the electronically readable data storage medium. Features, advantages and variants described for one claimed subject matter can be transferred to other claimed subject matters. In other words, claims oriented to devices/units can be improved by features that have been cited with respect to the method.

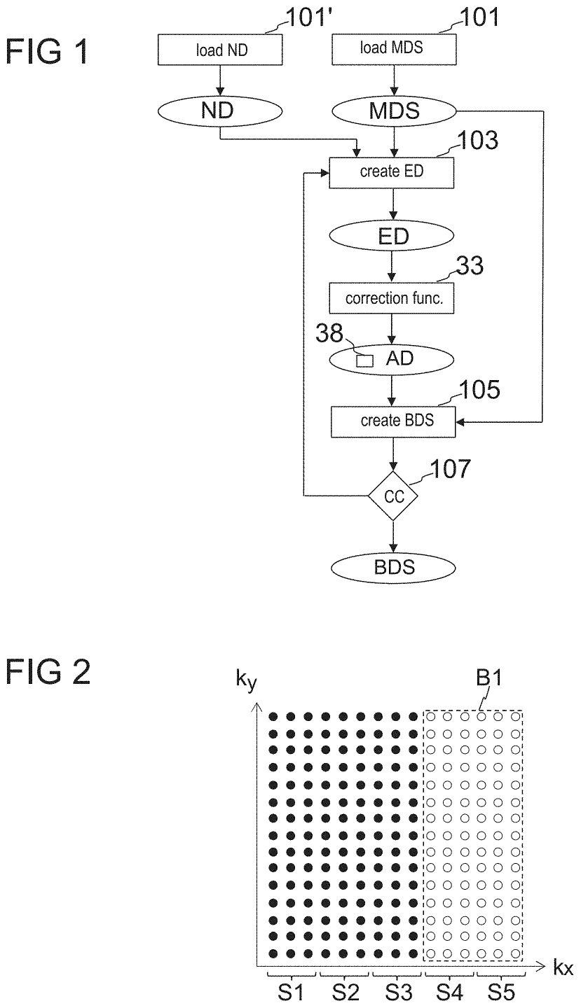

FIG. 1 is a schematic flow chart of an inventive method for preventing artifacts in image data BDS reconstructed from a measurement dataset MDS recorded using a PF technique.

In this case a measurement dataset MDS recorded using a PF technique is loaded (Block 101).

To record the measurement dataset MDS the k space can be segmented in a k space direction, for example can be sampled in a scan diagram schematically represented in FIG. 2. The k space to be sampled in accordance with Nyquist is in each case represented by circles. In this case filled circles correspond to sampled k space points, for which measurement data was thus recorded, and circles represented as unfilled correspond to unsampled k space points that are situated in the area B1, and for which measurement data is therefore missing.

In the example shown, ⅗ of the k space is recorded, and the PF factor is thus PF=⅗. The PF direction corresponds to the readout direction kx. In the phase encoding direction ky the k space, for k-space lines in which measurement data is recorded, can be sampled in full. It is also conceivable that in the phase encoding direction ky a parallel acquisition method (“ppa method” for short) known in principle, such as e.g. GRAPPA, is additionally employed, as a result of which the speed of recording of the measurement data can be further increased.

The recordings of the measurement data in a measurement dataset MDS can take place in segments. In this case e.g. the sketched segments S1, S2, S3, S4 and S5 could be recorded such that recording takes place in just the segments S1, S2 and S3 and not in the segments S4 and S5. The segments S4 and S5 thus correspond to the area B1 of missing measurement data. The measurement dataset MDS can in particular be recorded by means of a RESOLVE technique. When using a RESOLVE technique, the relaxation method (T2/T2*decay), on which the measurement data recorded in the various segments is based, is in each case identical for all segments. Hence RESOLVE techniques are particularly well suited for use in conjunction with PF techniques based on symmetry overlays, in particular in comparison to other recording techniques less symmetrical in the PF direction, such as e.g. EPI. When combining a RESOLVE technique with a PF technique it is directly possible to save measurement time thanks to the segmented recording, since thanks to the PF technique fewer segments are recorded (with the same repeat time TR for each segment). When combining EPI techniques with PF techniques, measurement time is generally not saved during the actual recording of the measurement data, since here the repeat time TR is not shortened (since it also influences the contrast of a resulting image dataset). However, for this a reduction in echo times TE and/or a reduction in blurring artifacts can be achieved, since the EPI echo train can be shortened thanks to the PF technique.

The loaded measurement dataset MDS can be a measurement dataset recorded using a parallel acquisition method, such as e.g. GRAPPA, with an increase in speed in a ppa direction which is not the PF direction. A measurement dataset recorded using a parallel acquisition method can also be supplemented initially in the ppa direction in accordance with the parallel acquisition method used, and the measurement dataset supplemented in this way can be loaded as a measurement dataset MDS for a method described here.

The loaded measurement dataset MDS can be a measurement dataset recorded in particular in the context of a diffusion-weighted MR measurement, using an EPI technique, in particular a RESOLVE technique. A measurement dataset recorded using an EPI technique can be corrected with phase correction methods known for EPI techniques, and the measurement dataset corrected in this way can be loaded as a measurement dataset MDS for a method described here.

On the basis of measurement data in the loaded measurement dataset MDS, input data ED is created for a trained correction function 33 (Block 103). Navigator data ND recorded in the context of the recording of the loaded measurement dataset MDS can also be loaded (Block 101′), said navigator data ND comprising further information about the object under examination measured with the loaded measurement dataset MDS, in particular about phase positions prevailing during the recording of the loaded measurement dataset MDS. Generated input data ED can also comprise navigator data ND.

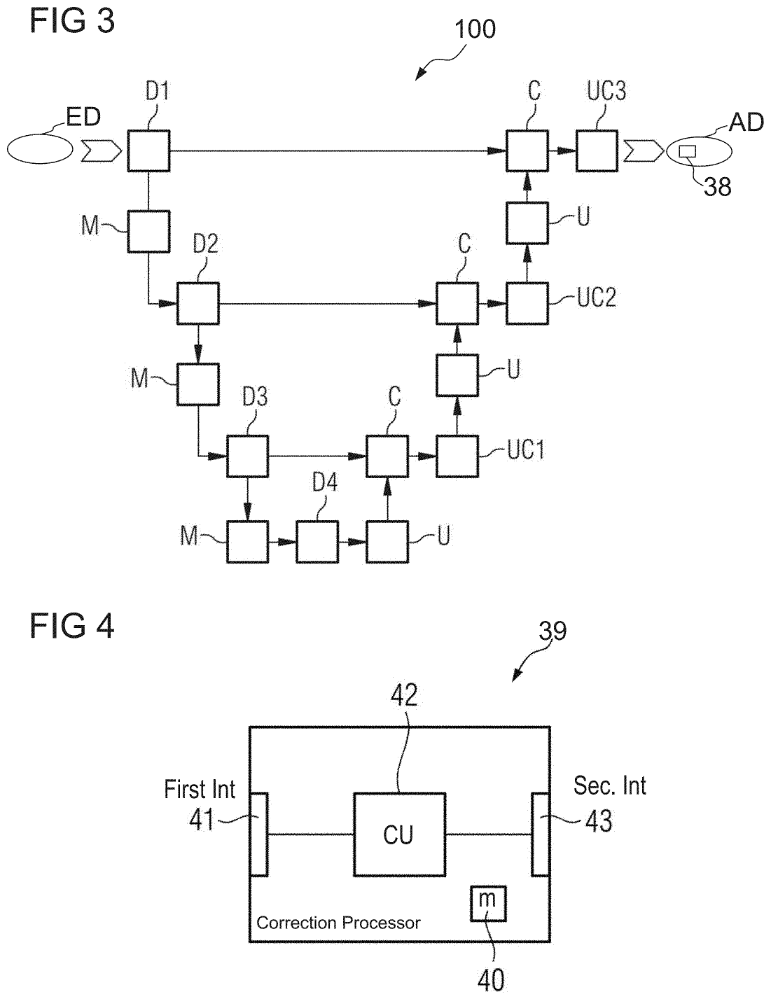

The correction function 33 described more fully with reference to FIG. 3 provides output data AD which comprises correction information 38 that is likewise loaded.

An image dataset BDS is created on the basis of measurement data in the loaded measurement dataset MDS and the loaded output data AD, if necessary after a consistency check 107, (Block 105). A consistency check 107 can comprise e.g. a comparison and/or an averaging of data comprised in the input data ED and data corresponding to this in the output data AD.

Additionally, or alternatively, an expected k space energy of the missing measurement data can be calculated on the basis of measurement data in the loaded measurement dataset, which e.g. was measured in a (radiofrequency) area in the k space identical in respect of the measured frequencies (in the example in FIG. 2, approximately the segments S1 and S2), in which area unmeasured measurement data in the measurement dataset is also situated (in the example in FIG. 2, approximately the segments S4 and S5), and can be compared with a corresponding k space energy of the output data (e.g. with missing measurement data as output data or with difference image data as output data).

If a deviation in the data in the input data from the corresponding data in the output data is established during the consistency check 107, said deviation for example being greater than a predefined threshold value, the output data can be rejected and/or input data ED can be generated afresh and supplied to the correction function 33.

FIG. 3 shows by way of example a basic structure of the trained correction function 33, in the present case as a U-net, which receives input data ED and provides output data AD. In the example shown the correction function 33 thus comprises a convolutional U-shaped neural network 100. In another variant the correction function 33 can also comprise a different (convolutional) neural network, e.g. an up-down network (not shown).

The U-shaped neural network 100 shown in FIG. 3 is a “convolutional neural network” (CNN). In its U-shaped architecture, a first half (descending branch, “down”) of the network is used for feature extraction and a second half (ascending branch, “up”) for increasing the resolution. As is known with such U-network architectures, the correction function 33 has different convolutions for reducing the resolutions, represented as D1 to D3 (“down convolution”), wherein a maximum extraction (“max pooling”) takes place therebetween, with M represented in FIG. 3. U components (“up sampling”) and UC components (“up convolution”) are provided in the ascending branch, as well as linking steps represented with C (concatenate).

The trained correction function 33 has been trained with training data.

In this case a computer-implemented method for providing the trained correction function can be employed, and comprises the steps:

receipt of training input data,
receipt of training output data, wherein the training output data is related to the training input data, e.g. is of the same or related type, or training input data and training output data are determined from data of the same or related type,
training a function based on the training input data and the training output data,
providing the trained function as a trained correction function.

In a computer-implemented method for creating correction data that corrects measurement data missing in a measurement dataset recorded using a PF technique, input data ED can be received that is created on the basis of measurement data in the measurement dataset.

By applying at least one trained correction function 33 to the input data ED it is possible to determine and provide output data AD comprising correction information 38 that corrects measurement data missing in the measurement dataset.

The input data can be image data created from the loaded measurement dataset, measurement data (in the k space) or hybrid spatial data, and can also comprise navigator data ND.

When creating the input data from the loaded measurement dataset it is possible to use e.g. measurement data from k space lines of the measurement dataset or measurement data from segments of the measurement dataset or all measurement data in the measurement dataset to create diverse input data.

The output data can likewise be image data, k space data or hybrid spatial data. The output data can in this case be data generated from the measurement data missing in the measurement dataset corresponding to input data generated from measurement data in the measurement dataset. It is however also conceivable for the output data to be data generated from a complete measurement dataset corresponding to input data generated from measurement data in the measurement dataset.

When using a correction function 33 comprising a U-shaped network 100, output data corresponding for example to the input data is provided, as a result of which input data and output data can easily be compared.

Some examples are described below of possible embodiments of the method described for creating correction data which corrects measurement data missing in a measurement dataset recorded using a PF technique.

In a simple embodiment the trained correction function 33 can obtain the measurement data in the loaded measurement dataset MDS and as output data can provide the measurement data missing in the loaded measurement dataset (in the example in FIG. 2 the measurement data of the area B1) or a complete measurement dataset (in the example in FIG. 2 measurement data of all segments S1 to S5). In this way measurement data for a complete measurement dataset from the input data and the output data as a whole is present, from which, if necessary after a consistency check, an image dataset with increased image sharpness can be reconstructed. If a complete measurement dataset is provided as output data, a consistency check can comprise e.g. a comparison and/or an averaging of measurement data comprised in the input data and measurement data in the output data corresponding thereto. If during the consistency check an impermissible deviation between the measurement data in the input data and the corresponding measurement data in the output data is established, a correction method can be initiated afresh, if necessary with changed input data.

It is also conceivable for output data also to be checked for consistency, in that (if it is not already present in this form) it is transformed into the k space and only k space data in the output data that corresponds to measurement data missing in the loaded measurement dataset is combined with the loaded measurement dataset, in order therefrom to reconstruct an image dataset BDS from the set of measurement data and k space data in the output data combined in this way to form a complete measurement dataset. In this way the measured measurement data in the loaded measurement dataset is taken over unchanged.

In a first concrete embodiment of the present disclosure it can be provided that at least one trained correction function is used, which as input data obtains an image dataset, in particular a set of complex image data, reconstructed from the loaded measurement dataset recorded using a PF technique, and provides a corresponding (complex) image dataset as output data, in which the image sharpness is increased compared to the input data, as if the loaded measurement dataset had been completely sampled in the PF direction. The increased image sharpness thus corresponds to an image sharpness as is achieved with reconstruction of image datasets from measurement datasets completely sampled in the PF direction. The absence of measurement data in the loaded measurement dataset has thus been corrected.

In a second concrete embodiment of the present disclosure it can be provided that at least one trained correction function is used, which as input data obtains an (in particular complex) image dataset reconstructed from the recorded measurement dataset, and provides an (in particular complex) image dataset as output data, which corresponds to a set of difference image data, which is a difference between an image dataset in which the image sharpness is increased compared to the input data, as if the loaded measurement dataset had been completely sampled in the PF direction, and the input data. In this way the trained correction function is trained in a focused manner to the differences between an image dataset reconstructed from the loaded measurement dataset and an image dataset with increased image sharpness as is achieved during reconstruction of image datasets from measurement datasets completely sampled in the PF direction, as a result of which image artifacts can be particularly well prevented. Furthermore, when difference data is taken into consideration it is particularly easily possible to carry out, e.g. by a comparison of expected k space energy and k space energy determined from the output data, a consistency check on the output data with the input data as a plausibility check on the output data. An image dataset with increased image sharpness can then be obtained by combining the input data with the output data. Thus, the output data can also be difference image data that corresponds to a difference between image data reconstructed from a measurement dataset corresponding to a completely recorded measurement dataset and image data reconstructed from the loaded measurement dataset which is recorded using a PF technique and is hence incomplete.

In a third embodiment of the present disclosure it can be provided that at least one trained correction function is used, which as input data obtains hybrid spatial data reconstructed from the recorded measurement dataset, and provides hybrid spatial data as output data, in which the image sharpness in the direction of the spatial coordinates of the hybrid space, in particular in the PF direction, is increased compared to the input data, as if the loaded measurement dataset had been completely sampled in the PF direction. By using hybrid spatial data as input data and output data the trained correction function is concentrated on the direction of the spatial component, preferably the direction incompletely sampled by the PF technique. Since when a PF technique is used radiofrequency information in the measured measurement data is absent only in the PF direction, e.g. the readout direction, no spatial localization of effects of this absence in the other recording direction, e.g. the phase encoding direction, is necessary. This procedure is in particular advantageous when using further techniques to increase the speed, such as e.g. ppa techniques in the non-PF direction following partial Fourier supplementing, in particular with an inventive correction method, since a ppa reconstruction of measurement data subsampled in this direction due to the further increase in speed is further possible.

Hybrid spatial data as input data can thus be hybrid spatial data transformed into the image space in the direction not completely recorded in the measurement dataset. For example, if the loaded measurement dataset is recorded in the readout direction kx and phase encoding direction ky, wherein kx also corresponds to the PF direction, the hybrid spatial data can be data in the x-ky hybrid space. By using hybrid spatial data as input data (and output data) the trained correction function is concentrated on the direction of the spatial component, preferably the direction incompletely sampled by the PF technique. The image sharpness in output data provided in this way can then be increased in the PF direction compared to the input data, as if the loaded measurement dataset had been completely sampled in the PF direction.

Image datasets with increased image sharpness can be reconstructed from the hybrid spatial data, e.g. by a further Fourier transform in the direction of the component of the hybrid spatial data still situated in the k space.

In a fourth embodiment of the present disclosure it can be provided that at least one trained correction function is used, which obtains input data created from different areas of the loaded measurement dataset, wherein the areas divide up the k space in the PF direction and in particular can be k space lines or segments. The trained correction function provides output data which is assigned to areas, in particular k space rows or segments, for which the measurement data is missing in the loaded measurement dataset MDS.

For example, it can be provided that at least one trained correction function is used, which as input data obtains reconstructed image datasets or sets of hybrid spatial data or measurement data (in the k space) from different areas of a recorded measurement dataset, and as output data provides image datasets or sets of hybrid spatial data or measurement data (in the k space) from areas missing in the recorded measurement dataset or from the recorded and unrecorded measurement data in the recorded measurement dataset. The loaded measurement dataset can in this case in particular already be recorded segment by segment, wherein one segment of the segment by segment recording of the measurement dataset can correspond to an area used for the generation of input data, but does not have to do so. By using areas, which can also comprise just one k space line, of the recorded measurement dataset in the generation of the input data, errors that can arise when individual areas of a recorded measurement dataset are combined can be prevented, without further (segment) fitting procedures that would otherwise have to be applied.

The input data can in this case for example be concatenated in the channel dimension, wherein different combinations are conceivable. On the one hand each individual area can be used in a concatenated manner, so that, taking the example of image data, image data in the individual areas of recorded measurement data in the loaded measurement dataset MDS is concatenated as input data and the output data is image data from areas of the missing measurement data. On the other hand, measurement data from individual areas of the loaded measurement dataset can be used to create input data, and a combination image of all areas can be provided as output data.

In segment by segment recording of measurement datasets the segments are often recorded with a small overlap to one another. The edges of the segments are then normally correlated using a classic fitting algorithm, in order to permit an improved combination of the measurement data in the individual segments. However, there are situations in which this fails. For these cases it may be advantageous if the segments are combined using a neural network such as the one described herein. Training data can be obtained for this purpose by readjusting the fitting of the segments manually or semi-automatically, and by using the combination of the optimally readjusted segments as training output data for the training.

An expedient, general development of the disclosure can provide that the input data furthermore, i.e. additionally, comprises navigator data ND that is assigned to the loaded measurement dataset MDS. As a result, information contained, e.g. in the navigator data, about a phase position prevailing during the recording of the measurement dataset, e.g. a background phase, can also be used in the trained correction function. As a result, a stabilization of the output data can be achieved, e.g. even if strong phase variations exist between individual recorded segments of the recorded measurement dataset.

Furthermore, the network architecture can be selected such that not only complete images but also partial segments of the k space in the k_{y} direction or even just individual k space lines can serve as input and output data. This has advantages in particular in the generation of training data.

Training input data and training output data for training the correction function 33 can be created from measurement datasets recorded completely (in accordance with Nyquist), e.g. by means of an EPI method or a RESOLVE method. Averaged training data can be used.

To this end measurement data in the completely recorded measurement dataset can be removed in accordance with a PF technique to generate training input data, and a reduced measurement dataset obtained in this way or areas of this reduced measurement dataset obtained in this way can either be used directly as training input data or to generate training input data, e.g. by reconstruction of image data or by transfer into a hybrid space. Further training input data can be obtained by a mirroring or a complex conjugation of cited reduced measurement datasets.

Training output data can be recorded from the completely recorded measurement datasets, e.g. by using as training output data the measurement data missing in the reduced measurement dataset which was the basis for generating training input data, or missing measurement data from areas of the k space, or reconstructing image data from this missing measurement data or generating hybrid spatial data as training output data. Difference image data as training output data can be generated by reconstructing image data from the completely recorded measurement dataset and images of the difference between this image data and image data reconstructed from the reduced measurement dataset.

To summarize, the above method describes a facility for correcting measurement data missing in measurement datasets recorded using a PF technique, so that an image quality of image data reconstructed from the measurement dataset is higher, without having to forgo the increase in speed of the recording thanks to the PF technique, by using a correspondingly trained neural network.

FIG. 4 shows a schematic diagram of an inventive correction processor 39, which is configured to carry out the inventive correction method and can for example be implemented as part of an evaluation device or controller of a magnetic resonance system, and in particular can serve as part of a postprocessing pipeline. The correction processor 39 can also be integrated into other computing devices or can be formed by these. In an exemplary embodiment, the correction processor 39 includes processing circuitry that is configured to perform one or more functions and/or operations of the correction processor 39. One or more of the components/units of the correction processor 39 may include processing circuitry that is configured to perform one or more corresponding functions and/or operations of the respective component(s).

To implement functional units the assignment device 39 has at least one processor and at least one memory storage means (memory) 40. Input data can be accepted via a first interface 41.

The trained correction function is applied in a correction unit 42, wherein the output data arising can be provided at a second interface 43. The correction unit 42 can for example also have an input data compilation unit as subunits, in which input data can be assigned e.g. to different channels, in order to form a common input dataset from diverse input data.

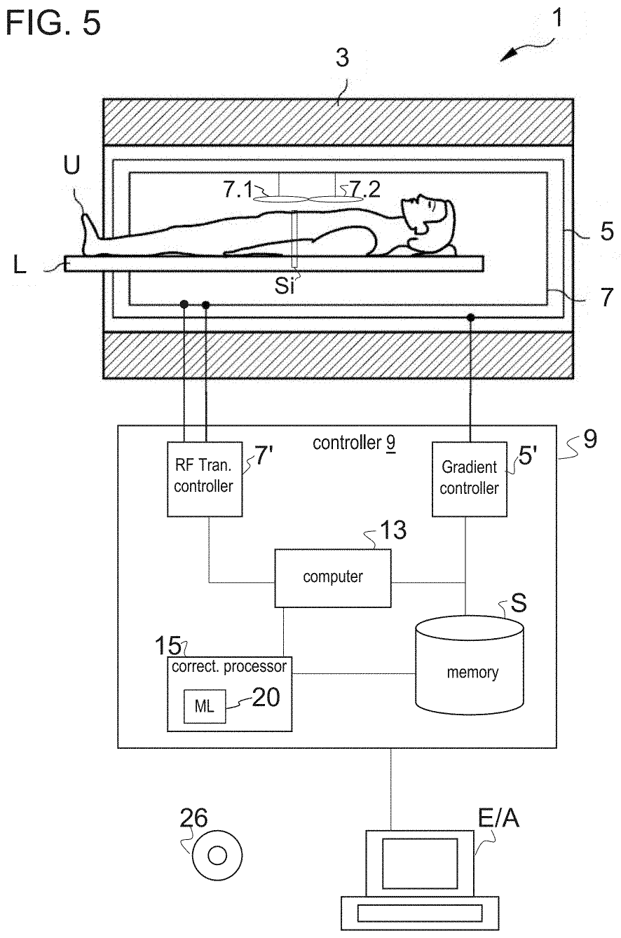

FIG. 5 schematically represents an inventive magnetic resonance (MR) system 1. The system 1 may include a magnet unit 3 configured to generate a constant magnetic field, a gradient unit 5 configured to generate gradient fields, a radio-frequency (RF) unit 7 configured to irradiate and receive radio-frequency (RF) signals, and a controller 9 configured to carry out an inventive method according to the disclosure. The magnet unit 3, the gradient unit 5, and the RF unit 7 may collectively be referred to as a MR scanner.

In FIG. 5 these subunits of the magnetic resonance system 1 are represented only roughly. In particular, the radiofrequency unit 7 can consist of multiple subunits, for example of multiple coils such as the schematically shown coils 7.1 and 7.2 or more coils that can be configured either only for transmitting radiofrequency signals or only for receiving the triggered radiofrequency signals or for both.

To examine an object under examination U, for example a patient or else a phantom, the object under examination U can be introduced into the imaging volume of the magnetic resonance system 1 on a couch L. The slice or the slab S1 represents an exemplary target volume of the object under examination, from which echo signals can be recorded and are to be captured as measurement data.

The controller 9 may be configured to control the magnetic resonance system 1 and can, in particular, control the gradient unit 5 by means of a gradient controller 5′ and the radiofrequency (RF) unit 7 by means of a radiofrequency (RF) transceiver controller 7′. The radiofrequency unit 7 can in this case comprise multiple channels, on which signals can be sent or received.

The radiofrequency unit 7 is, together with its radiofrequency transceiver controller 7′, responsible for the generation and irradiation (transmission) of a radiofrequency alternating field for manipulation of the spins in an area to be manipulated (for example in slices S to be scanned) of the object under examination U. In this case, the center frequency of the radiofrequency alternating field, also referred to as the B1 field, is generally wherever possible set such that it lies close to the resonance frequency of the spins to be manipulated. Deviations between the center frequency and the resonance frequency are referred to as off-resonance. To generate the B1 field currents controlled by means of the radiofrequency transceiver controller 7′ are applied to the RF coils in the radiofrequency unit 7.

The controller 9 further comprises a correction processor 15, which comprises a module 20 for machine learning, and with which inventive methods can be carried out. The controller 9 is overall configured to carry out an inventive method.

A computing unit (computer) 13 comprised by the controller 9 is configured to execute all computing operations required for the necessary measurements and determinations. To this end required or hereby determined interim results and results can be stored in a memory unit S of the controller 9. The units represented should not hereby absolutely be understood to be physically separate units, but merely represent a subdivision into meaningful units, which however can also be implemented in fewer or even in just one single physical unit. In an exemplary embodiment, the controller 9 includes processing circuitry that is configured to perform one or more functions and/or operations of the controller 9. One or more of the components/units of the controller 9 may include processing circuitry that is configured to perform one or more corresponding functions and/or operations of the respective component(s).

Control commands can be routed to the magnetic resonance system and/or results from the controller 9 such as e.g. image data can be displayed via an input/output device E/A of the magnetic resonance system 1, e.g. by a user. The input/output device E/A may be an input/output interface, such as a general-purpose computer.

A method described herein can also be present in the form of a computer program product which comprises a program and implements the described method on a controller 9 when it is executed on the controller 9. Likewise, an electronically readable data storage medium (memory) 26 with electronically readable control information stored thereon can be present which comprises at least one such computer program product as just described and is configured such that when the data storage medium 26 is used in a controller 9 of a magnetic resonance system 1 it carries out the described method.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure.

Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer-implemented method for creating correction data adapted to correct corrects missing or unrecorded measurement data in a measurement dataset recorded using a partial Fourier technique, the method comprising:
receiving input data created based on measurement data of the measurement dataset;
applying, by a processor, at least one trained correction function to the input data to determine correction information configured to correct missing measurement data of the measurement dataset; and
providing the correction information in electronic form as an output data file.

2. The method as claimed in claim 1, wherein the at least one trained correction function comprises a convolutional U-shaped neural network or an up-down network.

3. The method as claimed in claim 1, wherein the input data is image data, measurement data k-space, or hybrid spatial data.

4. The method as claimed in claim 3, wherein the input data further comprises navigator data.

5. The method as claimed in claim 1, wherein the input data includes hybrid spatial data transformed into an image space in a direction not completely recorded in the measurement dataset.

6. The method as claimed in claim 1, wherein the input data is created based on:
measurement data of k-space lines of the measurement dataset,
measurement data of segments of the measurement dataset, or
all measurement data in the measurement dataset.

7. The method as claimed in claim 1, wherein the correction information includes image data, k-space data, or hybrid spatial data.

8. The method as claimed in claim 1, wherein the correction information is difference image data that corresponds to a difference between image data reconstructed from a measurement dataset corresponding to a completely recorded measurement dataset and image data reconstructed from a loaded measurement dataset.

9. The method as claimed in claim 1, wherein the correction information includes data generated from measurement data missing in the measurement dataset corresponding to input data generated from measurement data in the measurement dataset.

10. The method as claimed in claim 1, wherein the correction information includes data generated from a complete measurement dataset corresponding to input data generated from measurement data in the measurement dataset.

11. A computer program product, embodied on a non-transitory computer-readable storage medium, that is loadable into a memory of a controller of a magnetic resonance system and includes a computer program, when the computer program is executed by the controller, controls the controller to perform the method as claimed in claim 1.

12. A non-transitory computer-readable storage medium having a computer program stored thereon, when executed by the processor, controls the processor to perform the method as claimed in claim 1.

13. A method for preventing artifacts in image data reconstructed from a measurement dataset recorded using a partial Fourier (PF) technique, the method comprising:
loading a measurement dataset recorded using the PF technique;
loading correction information determined based on measurement data in the loaded measurement dataset according to the method of claim 1; and
creating an image dataset based on the measurement data in the loaded measurement dataset and the correction information.

14. A correction processor for creating correction data adapted to correct missing measurement data of a measurement dataset recorded using a partial Fourier (PF) technique, the correction processor comprising:
a first interface configured to receive input data created based on measurement data in the measurement dataset;
processing circuitry configured to apply at least one trained correction function to the input data to determine correction information; and
a second interface configured to provide the correction information in electronic form as an output data file.

15. A magnetic resonance (MR) system comprising:
a MR scanner; and
a controller including the correction processor of claim 14.

16. The MR system as claimed in claim 15, wherein the MR scanner includes a magnet unit, a gradient unit, and a radiofrequency unit.
